(19) United States
(12) Patent Application Publication
(10) Pub. No.: US 2025/0113437 A1
(43) Pub. Date: Apr. 3, 2025

(54) BUS BAR WITH TAB AND CIRCUIT ASSEMBLY

(71) Applicant: Sumitomo Wiring Systems, Ltd., Yokkaichi-shi (JP)

(72) Inventor: Max MATSUMURA, Farmington Hills, MI (US)

(21) Appl. No.: 18/479,590

(22) Filed: Oct. 2, 2023

(51) Int. Cl. H05K 1/18; H02B 1/20

(52) U.S. Cl. CPC H05K 1/18; H02B 1/20; H05K 2201/10272

(57) ABSTRACT

A circuit assembly includes a printed circuit board having a plurality of slots; and a bus bar including a first member, a first terminal and a second terminal configured to be seated within a corresponding one of the plurality of slots, the first member being an elongated member having a bottom edge, and the first terminal and the second terminal are spaced apart from each other and disposed on the bottom edge of the first member. The second terminal includes a tab protruding outwardly from the surface. The tab is deformed to the compressed position as the second terminal is passed through the corresponding one of the plurality of slots and returns to the uncompressed position when the tab passes through the corresponding slot so as to secure the second terminal therein.

### TECHNICAL FIELD

The present specification generally relates to a bus bar for use with a circuit board.

### BACKGROUND

Bus bars 200 are mounted to a top surface of a circuit board 300 and may be configured to provide power to the electronic components 400 mounted to the circuit board 300. A depiction of a conventional circuit board 300 is shown in FIGS. 1 and 2. The bus bar 200 includes an elongated body having a bottom edge. A plurality of terminals 202 are disposed on the bottom edge of the elongated body and are configured to be seated into a respective slot of the circuit board 300.

The bus bar 200 is mounted onto the circuit board 300 and the electronic components 400, such as fuses and relays, may be mounted to the circuit board 300 subsequent to the bus bar 200. During the mounting process of the electronic components 400, a force is applied to the circuit board 300 which may change the position of the bus bar 200 relative to the circuit board 300. For instance, the bottom edge of the bus bar 200 may be angled by having one end of the bus bar 200 displaced further from the circuit board 300 than the other end of the bus bar 200. In addition, during the manufacture of the bus bar 200 deformation may occur during the reflow process which results in the lower edge of the bus bar 200 having curvature which may place one end of the bus bar 200 higher relative to the circuit board 300 than the other end of the bus bar 200.

To alleviate this problem, some of the terminals 202 of the bus bars 200 are formed as a prong 204, e.g. has a pair of legs which are spaced apart. The prong 204 is inserted into the slot of the circuit board by a first tool and a second tool is required to splay the legs so as to angle the legs away from each other to form a shape similar to a pair of rabbit ears. Thus, the bus bar 200 remains in position when the electronic components 400 are mounted. However, the tooling adds extra steps to the manufacturing process.

Accordingly, it remains desirable to the steps required to assembly a circuit assembly.

### SUMMARY

A bus bar includes a first member formed of an electrically conductive material. The first member is an elongated member having a first surface opposite a second surface and a top edge opposite a bottom edge. The first terminal is disposed on the bottom edge of the bus bar and includes a first outer terminal surface spaced apart from a first inner terminal surface so as to define a thickness of the first terminal. The first terminal is coplanar with the first member. The bus bar also includes a second terminal disposed on the bottom edge of the first member and spaced apart from the first terminal. The second terminal includes a second outer terminal surface spaced apart from a second inner terminal surface so as to define a thickness of the second terminal. The second terminal includes a tab protruding outwardly from one of the second outer terminal surface and the second inner terminal surface.

In one aspect, the second terminal may include a second shoulder disposed on the bottom edge of the first member and the first terminal may include a first shoulder disposed on the bottom edge of the first member.

In another aspect, the second terminal may further include a second neck and the tab is disposed on the second neck. In such an aspect, the second shoulder and the second neck may have a thickness equal to each other. In yet another aspect, an opening is formed behind the tab.

In another aspect, the first member includes a main body and a pair of legs disposed on opposite ends of the main body. In such an aspect, the second terminal is a pair of second terminals and one of the pair of second terminals is disposed on one of the pair of legs and the other of the pair of second terminals is disposed on the main body. The first terminal may be a pair of first terminals and one of the pair of first terminals is disposed between the pair of second terminals.

In another aspect of the disclosure, a circuit assembly is provided. The circuit assembly includes a printed circuit board having a plurality of slots and a bus bar. The bus bar includes a first member, a first terminal and a second terminal. The first terminal and the second terminal are configured to be seated within a corresponding one of the plurality of slots. The first member is an elongated member having a first surface opposite a second surface and a top edge opposite a bottom edge. The first terminal and the second terminal are spaced apart from each other and disposed on the bottom edge of the first member.

The first terminal includes a first outer terminal surface spaced apart from a first inner terminal surface so as to define a thickness of the first terminal. The first terminal is coplanar with the first member. The second terminal includes a second outer terminal surface spaced apart from a second inner terminal surface so as to define a thickness of the second terminal. The thickness of the second terminal is smaller than a width of the slot. The second terminal includes a tab protruding outwardly from one of the second outer terminal surface and the second inner terminal surface. The tab is a resilient member configured to deform to a compressed position and return to an uncompressed position. In operation, the tab is deformed to the compressed position as the second terminal is passed through the corresponding one of the plurality of slots and returns to the uncompressed position when the tab passes through the corresponding slot so as to secure the second terminal therein.

In one aspect of the circuit assembly, the second terminal includes a second shoulder and the second shoulder is disposed on the bottom edge of the first member and the first terminal includes a first shoulder and the first shoulder is disposed on the bottom edge of the first member.

In one aspect of the circuit assembly, the second terminal further includes a second neck and the tab is disposed on the second neck. The second neck is seated within the corresponding slot of the plurality of slots.

In one aspect, the second shoulder and the second neck have a thickness equal to each other. An opening may be formed behind the tab.

In one aspect, the first member includes a main body and a pair of legs disposed on opposite ends of the main body.

In one aspect, the second terminal may be a pair of second terminals and one of the pair of second terminals is disposed on one of the pair of legs and the other of the pair of second terminals is disposed on the main body. The first terminal may be at least a pair of first terminals and one of the pair of first terminals is disposed between the pair of second terminals.

### Advantageous Effects

Accordingly, the circuit assembly includes a bus bar having a tab that is configured to hold the bus bar in position through the electronic component mounting process without the need for additional tooling.

### BRIEF DESCRIPTION OF THE DRAWINGS

The embodiments set forth in the drawings are illustrative and exemplary in nature and not intended to limit the subject matter defined by the claims. The following description of the illustrative embodiments can be understood when read in conjunction with the following drawings, where like structure is indicated with like reference numerals and in which:

FIG. 1 is a perspective view of a conventional of a circuit board assembly;

FIG. 2 is a side view of the circuit board assembly shown in FIG. 1;

FIG. 3 is a side view of a circuit assembly according to one or more aspects described herein;

FIG. 4A is a side view of a bus bar according to one or more aspects described herein;

FIG. 4B is a side view of an aspect of the bus bar shown in FIG. 4A with the tab disposed on the second inner terminal surface;

FIG. 5 is a top-down view of the bus bar shown in FIG. 4;

FIG. 6 is a bottom perspective of the bus bar shown in FIG. 4;

FIG. 7 is a cross-sectional view of the circuit assembly shown in FIG. 3, taken along line 7-7; and

FIG. 8 is a close up view of the second terminal.

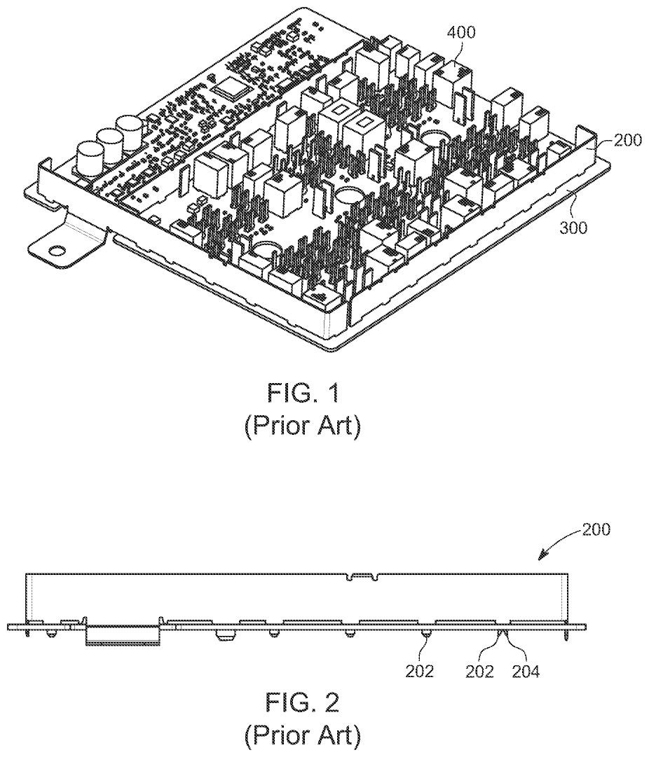

### DETAILED DESCRIPTION OF PREFERRED EMBODIMENTS

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed. Directional terms such as top, bottom, left and right are made in reference to the upright orientation of the drawings, and is indicated by directional arrows. The terms height, width, thickness and length are used in reference with the accompanying arrow.

Provided is a bus bar and a circuit assembly utilizing the bus bar. The circuit assembly includes a printed circuit board having a plurality of slots and a bus bar. The bus bar includes a first member, a first terminal and a second terminal. The first terminal and the second terminal are configured to be seated within a corresponding one of the plurality of slots. The first member is an elongated member having a first surface opposite a second surface and a top edge opposite a bottom edge. The first terminal and the second terminal are spaced apart from each other and disposed on the bottom edge of the first member. The first terminal includes a first outer terminal surface spaced apart from a first inner terminal surface so as to define a thickness of the first terminal. The first terminal is coplanar with the first member. The second terminal includes a second outer terminal surface spaced apart from a second inner terminal surface so as to define a thickness of the second terminal. The thickness of the second terminal is smaller than a width of the slot. The second terminal includes a tab protruding outwardly from one of the second outer terminal surface and the second inner terminal surface. The tab is a resilient member configured to deform to a compressed position and return to an uncompressed position. In operation, the tab is deformed to the compressed position as the second terminal is passed through the corresponding one of the plurality of slots and returns to the uncompressed position when the tab passes through the corresponding slot so as to secure the second terminal therein. Accordingly, the bus bar is held in position through the mounting process of the electronic components without the need for an additional tool.

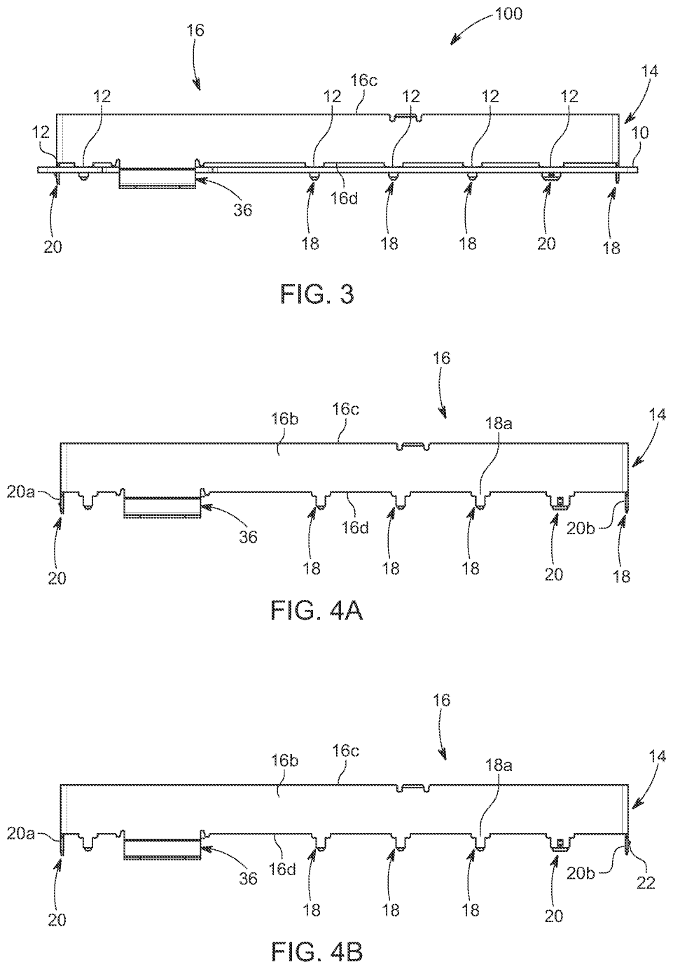

With reference now to FIG. 3, a circuit assembly 100 is provided. The circuit assembly 100 includes a printed circuit board 10 having a plurality of slots 12 and a bus bar 14. The printed circuit board 10 is a board having an insulating layer and a conductive pattern (not shown) formed by printed wiring. The conductive pattern provides power to the electric components mounted thereon. The printed circuit board 10 includes a plurality of slots 12. Each slot 12 extends through the printed circuit board 10 and may be dimensioned similar to each other.

With reference now to FIGS. 4A-6, a description of the bus bar 14 is provided. The bus bar 14 includes a first member 16 formed of an electrically conductive material. The first member 16 is an elongated member formed of a planar sheet of electrically conductive material such as steel. The first member 16 has a first surface 16a opposite a second surface 16b and a top edge 16c opposite a bottom edge 16d.

The bus bar 14 further includes a first terminal 18 and a second terminal 20. In one aspect, the bus bar 14 includes one or more first terminals 18 and one or more second terminals 20. The first terminal 18 and the second terminal 20 are configured to be inserted into a respective slot 12 formed on the printed circuit board 10. Thus, it should be appreciated that the slots 12 are arranged on the printed circuit board 10 to conform with the bottom edge 16d of the bus bar 14.

The first terminal 18 is disposed on the bottom edge 16d of the bus bar 14 and includes a first outer terminal surface 18a spaced apart from a first inner terminal surface 18b so as to define a thickness “T18” of the first terminal 18. The first terminal 18 is coplanar with the first member 16 of the bus bar 14. The second terminal 20 is also disposed on the bottom edge 16d of the first member 16 of the bus bar 14 and is spaced apart from the first terminal 18. The second terminal 20 includes a second outer terminal surface 20a spaced apart from a second inner terminal surface 20b so as to define a thickness “T20” of the second terminal 20. The second terminal 20 includes a tab 22 protruding outwardly from one of the second outer terminal surface 20a and the second inner terminal surface 20b. FIG. 4A shows the tab 22 disposed on the second outer terminal surface 20a and FIG. 4B shows the tab disposed on the second inner terminal surface 20b.

The bus bar 14 may be formed through a stamping process wherein the first member 16, the first terminal 18, and the second terminal 20 are formed as a singular piece from a sheet of conductive material. In such an aspect, a width “W14” of the bus bar 14 is uniform absent any manufacturing tolerance in the production of the sheet of conductive material. The slots 12 have a width “W12” which is greater than a width “W18” of the first terminal 18 and a width “W20” of the second terminal 20. Thus, the slots 12 are dimensioned to receive the first terminal 18 and the second terminal 20 with a clearance between the inner surface of the slot 12 and the outer surface of the first terminal 18 and the second terminal 20.

With reference again to FIG. 4, the second terminal 20 may include a second shoulder 24 disposed on the bottom edge 16d of the first member 16 and the first terminal 18 may include a first shoulder 26 disposed on the bottom edge 16d of the first member 16. In one aspect, the second terminal 20 includes a pair of second shoulders 24 disposed on opposite sides of the second terminal 20. Likewise, the first terminal 18 may include a pair of first shoulders 26 disposed on opposite sides of the first terminal 18. The first shoulder 26 and the second shoulders 24 form a rounded portion of the corresponding first terminal 18 and second terminal 20.

The first terminal 18 may further include a first neck 28. The first neck 28 is interposed between the first shoulders 26 and is formed as a singular piece. Likewise, the second terminal 20 may further include a second neck 30. The second neck 30 is interposed between the second shoulders 24 and is formed as a singular piece. The tab 22 is disposed on the second neck 30. In instances where the bus bar 14 is formed from a stamped piece of sheet metal, the second shoulder 24 and the second neck 30 have a thickness equal to each other. In one aspect, the tab 22 is formed by a punch process wherein the tab 22 is punched outwardly from the neck so as to form an opening is behind the tab 22. The opening is helpful in allowing the tab 22 to deform to a compressed state as the opening provides the tab 22 with a space to be pushed into.

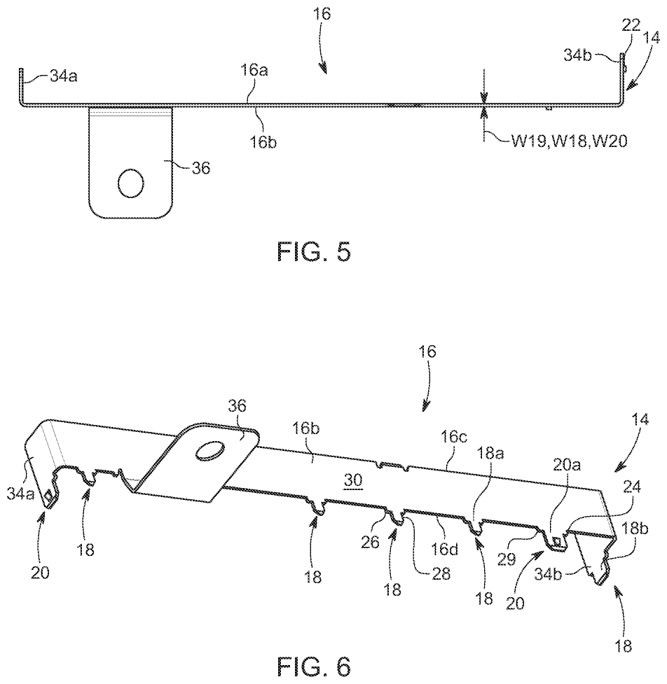

With reference now to FIGS. 5 and 6, the first member 16 includes a main body 32 and a pair of legs 34 (a first leg 34a and a second leg 34b) disposed on opposite ends of the main body 32. The legs 34 are generally orthogonal to the main body 32. The bus bar 14 may include a pair of second terminals 20 wherein one of the pair of second terminals 20 is disposed on leg 34a and the other of the pair of second terminals 20 is disposed on the main body 32. Thus, the second terminals 20 are configured to secure opposite ends of the bus bar 14 to the printed circuit board 10. It should be appreciated that the bus bar 14 is depicted as being generally U-shaped, and that a bus bar 14 having a different shape without deviating from the scope of the appended claims. For instance, the bus bar 14 may be a single continuous member fixed along an axis, or may completely bound the periphery of the circuit board 10.

The bus bar 14 is illustratively shown as having four first terminals 18 disposed along the bottom edge 16d of the first member 16 and between the pair of second terminals 20. A fifth first terminal 18 is disposed on leg 34b of the bus bar 14. The bus bar 14 is illustratively depicts an embodiment where the first terminals 18 and the second terminals 20 are not identical in shape. For instance, the second terminal 20 that is disposed on leg 34a has a neck that is wider than the neck of the second terminal 20 disposed on the first member 16. Further, the second terminal 20 is shaped identical to the first terminal 18 disposed on leg 34b.

In another aspect of the disclosure, a circuit assembly 100 is provided. The circuit assembly 100 includes a printed circuit board 10 and a bus bar 14. The printed circuit board 10 and the bus bar 14 described above may be incorporated in the circuit assembly 100 described herein and a detailed description of the printed circuit board 10 and the bus bar 14 are purposefully omitted to alleviate redundancy. The bus bar 14 is electrically conductive and is configured to provide power to the electric components mounted on the printed circuit board 10. The bus bar 14 includes a power terminal 36 configured to connect with a power supply. The power terminal 36 is formed of the same material as the bus bar 14 and may include an eyelet for coupling a terminal of a wire (not shown) connected to a power supply.

During assembly, the bus bar 14 is mounted onto the printed circuit board 10 by a tool that grips and positions the bus bar 14 to align the first terminals 18 and the second terminals 20 with a corresponding slot 12 of the printed circuit board 10. The tool then presses the bus bar 14 onto the printed circuit board 10 wherein the first terminals 18 and the second terminals 20 are seated into a corresponding slot 12. The bus bar 14 is pressed onto the printed circuit board 10 and the first shoulders 26 and second shoulders 24 of the first terminal 18 and the second terminal 20 are wider than a length of a corresponding slot 12, spacing the bottom edge 16d of the bus bar 14 away from the top surface of the printed circuit board 10 a distance equal to a height of the first shoulders 26 and second shoulders 24.

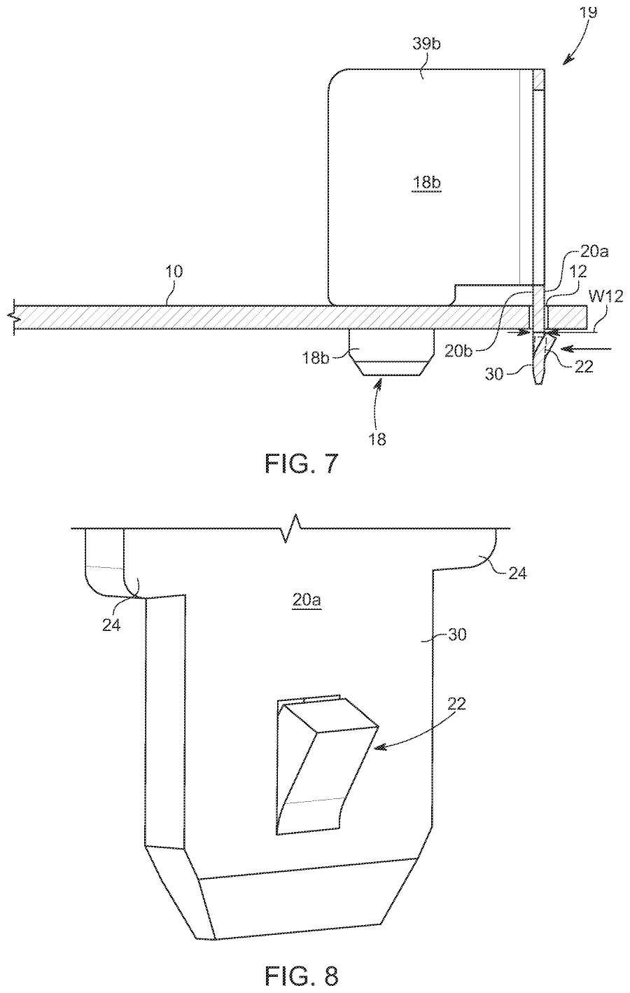

With reference now to FIGS. 7 and 8, the tab 22 is deformed to the compressed position when being pressed through the slot 12 and is pressed inwardly into the opening as indicated by the dashed lines and arrow in FIG. 7. As the tab 22 passes the slot 12, the tab 22 is free to return to an uncompressed position as indicated in solid line. In the uncompressed position, the tab 22 extends past the slot 12 and faces a bottom surface of the printed circuit board 10 so as to prevent the bus bar 14 from being lifted away from the printed circuit board 10. Further, the bus bar 14 takes advantage of the motion of the tool and thus a second tool is not required to secure the terminals of the bus bar 14 into position with respect to the printed circuit board 10 relative to the bus bar 14s of the prior art that use prongs. It should be appreciated that the dimension of the tab 22 is provided for illustrative purposes, and that the tab 22 may be dimensioned otherwise so long as the tab 22 is able to compress and pass through the slot 12 and extend outwardly so as to be positioned underneath the bottom surface of the printed circuit board 10 when the tab 22 is past the slot 12.

### Advantageous Effects

Accordingly, the circuit assembly 100 includes a bus bar 14 having a tab 22 that is configured to hold the bus bar 14 in position through the electronic component mounting process without the need for additional tooling.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. A bus bar comprising:
a first member, the first member being an elongated member having a first surface opposite a second surface and a top edge opposite a bottom edge;
a first terminal disposed on the bottom edge and including a first outer terminal surface spaced apart from a first inner terminal surface so as to define a thickness of the first terminal and coplanar with the first member; and
a second terminal disposed on the bottom edge of the first member and spaced apart from the first terminal, the second terminal including a second outer terminal surface spaced apart from a second inner terminal surface so as to define a thickness of the second terminal, the second terminal including a tab protruding outwardly from one of the second outer terminal surface and the second inner terminal surface.

2. The bus bar according to claim 1, wherein the second terminal includes a second shoulder and the disposed on the bottom edge of the first member.

3. The bus bar according to claim 2, wherein the first terminal includes a first shoulder and the disposed on the bottom edge of the first member.

4. The bus bar according to claim 3, wherein the second terminal further includes a second neck, the tab disposed on the neck portion.

5. The bus bar according to claim 4, wherein second shoulder and the second neck have a thickness equal to each other.

6. The bus bar according to claim 5, wherein an opening is formed behind the tab.

7. The bus bar according to claim 6, wherein the first member includes a main body and a pair of legs disposed on opposite ends of the main body.

8. The bus bar according to claim 7, wherein the second terminal is a pair of second terminals.

9. The bus bar according to claim 8, wherein one of the pair of second terminals is disposed on one of the pair of legs and the other of the pair of second terminals is disposed on the main body.

10. The bus bar according to claim 9, wherein the first terminal is at least a pair of first terminals and one of the pair of first terminals is disposed between the pair of second terminals.

11. A circuit assembly comprising:
a printed circuit board having a plurality of slots; and
a bus bar including a first member, a first terminal and a second terminal configured to be seated within a corresponding one of the plurality of slots, the first member being an elongated member having a first surface opposite a second surface and a top edge opposite a bottom edge, and the first terminal and the second terminal are spaced apart from each other and disposed on the bottom edge of the first member, the first terminal including a first outer terminal surface spaced apart from a first inner terminal surface so as to define a thickness of the first terminal and is coplanar with the first member; and wherein
the second terminal includes a second outer terminal surface spaced apart from a second inner terminal surface so as to define a thickness of the second terminal the thickness of the second terminal is smaller than a width of the slot, the second terminal including a tab protruding outwardly from one of the second outer terminal surface and the second inner terminal surface, wherein the tab is a resilient member configured to deform to a compressed position and return to an uncompressed position, wherein the tab is deformed to the compressed position as the second terminal is passed through the corresponding one of the plurality of slots and returns to the uncompressed position when the tab passes through the corresponding slot so as to secure the second terminal therein.

12. The circuit assembly according to claim 11, wherein the second terminal includes a second shoulder and the disposed on the bottom edge of the first member.

13. The circuit assembly according to claim 12, wherein the first terminal includes a first shoulder and the disposed on the bottom edge of the first member.

14. The circuit assembly according to claim 13, wherein the second terminal further includes a second neck, the tab disposed on the neck portion, the second neck seated within the corresponding slot of the plurality of slots.

15. The circuit assembly according to claim 14, wherein second shoulder and the second neck have a thickness equal to each other.

16. The circuit assembly according to claim 15, wherein an opening is formed behind the tab.

17. The circuit assembly according to claim 16, wherein the first member includes a main body and a pair of legs disposed on opposite ends of the main body.

18. The circuit assembly according to claim 17, wherein the second terminal is a pair of second terminals.

19. The circuit assembly according to claim 18, wherein one of the pair of second terminals is disposed on one of the pair of legs and the other of the pair of second terminals is disposed on the main body.

20. The circuit assembly according to claim 19, wherein the first terminal is at least a pair of first terminals and one of the pair of first terminals is disposed between the pair of second terminals.
